(19) United States
(12) Patent Application Publication
(10) Pub. No.: US 2024/0105420 A1
(43) Pub. Date: Mar. 28, 2024

(54) DATA GENERATION APPARATUS, DATA GENERATION METHOD, AND COMPUTER-READABLE STORAGE MEDIUM

(71) Applicant: Kioxia Corporation, Tokyo (JP)

(72) Inventors: Katsuyoshi KODERA, Yokohama Kanagawa (JP); Shoji MIMOTOGI, Yokohama Kanagawa (JP); Shunko MAGOSHI, Minato Tokyo (JP); Ryuji OGAWA, Yokohama Kanagawa (JP); Taiki KIMURA, Kawasaki Kanagawa (JP)

(73) Assignee: Kioxia Corporation, Tokyo (JP)

(21) Appl. No.: 18/332,203

(22) Filed: Jun. 9, 2023

(30) Foreign Application Priority Data
Sep. 20, 2022 (JP) 2022-149354

(51) Int. Cl. H01J 37/317

(52) U.S. Cl. CPC H01J 37/3174; H01J 2237/31762; H01J 2237/31776

(57) ABSTRACT

A data generation apparatus of one embodiment includes a processing unit, an evaluation unit, and a conversion unit. The processing unit designs, through optical proximity correction based on a target pattern formed on a substrate using the photomask, a mask pattern corresponding to the target pattern and including a plurality of rectangular regions. The evaluation unit evaluates the mask pattern using a cost function having, as a parameter, a jog length indicating a length of each of the rectangular regions included in the mask pattern in a first direction. The conversion unit converts mask pattern data indicating the mask pattern with an evaluation that meets a predetermined condition to drawing data corresponding to a variable shaped beam drawing process.

### CROSS-REFERENCE TO RELATED APPLICATIONS

This application is based upon and claims the benefit of priority from Japanese Patent Application No. 2022-149354, filed on Sep. 20, 2022; the entire contents of which are incorporated herein by reference.

### FIELD

Embodiments described herein relate generally to a data generation apparatus, a data generation method, and a computer-readable storage medium.

### BACKGROUND

A variable shaped beam (VSB) electron beam lithography apparatus is used as an apparatus that forms a mask pattern on a photomask. In such an electron beam lithography apparatus, a maximum shot region that can be drawn with one electron beam irradiation (one shot) is determined. The number of shots required to complete a mask pattern varies depending on the relationship between the shape of the mask pattern and the shape of the maximum shot region. An increase in the number of shots, for example, increases the drawing time, which causes a reduction in the productivity of photomasks.

According to one embodiment of the present invention, a data generation apparatus that executes a process for generating drawing data for forming a mask pattern on a photomask is provided. The data generation apparatus includes a processing unit, an evaluation unit, and a conversion unit. The processing unit designs, through optical proximity correction based on a target pattern formed on a substrate using the photomask, a mask pattern corresponding to the target pattern and including a plurality of rectangular regions. The evaluation unit evaluates the mask pattern using a cost function having, as a parameter, a jog length indicating a length of each of the rectangular regions included in the mask pattern in a first direction. The conversion unit converts mask pattern data indicating the mask pattern with an evaluation that meets a predetermined condition to drawing data corresponding to a variable shaped beam drawing process.

### BRIEF DESCRIPTION OF THE DRAWINGS

FIG. 1 is a diagram illustrating an example of the hardware configuration of a data generation apparatus of a first embodiment;

FIG. 2 is a diagram illustrating an example of the function configuration of the data generation apparatus of the first embodiment;

FIG. 3 is a diagram illustrating an example of a target pattern, a mask pattern, and a VSB drawing pattern of the first embodiment;

FIG. 4 is a diagram illustrating a first example of the mask pattern of the first embodiment;

FIG. 5 is a diagram illustrating a second example of the mask pattern of the first embodiment;

FIG. 6 is a diagram illustrating an example of an ideal mask pattern shape of the first embodiment;

FIG. 7 is a flowchart illustrating an example of a process in the data generation apparatus of the first embodiment;

FIG. 8 is a diagram illustrating an example of an end misalignment amount δ in a mask pattern of a second embodiment;

FIG. 9 is a diagram illustrating an example of a pattern width in a mask pattern and a maximum shot width in a maximum shot region of a third embodiment; and

FIG. 10 is a diagram illustrating an example of the flow of a process in designing a VSB drawing pattern from a target pattern using an ILT in a modification.

### DETAILED DESCRIPTION

In general, according to one embodiment, a data generation apparatus that executes a process for generating drawing data for forming a mask pattern on a photomask is provided. The data generation apparatus includes a processing unit, an evaluation unit, and a conversion unit. The processing unit designs, through optical proximity correction based on a target pattern formed on a substrate using the photomask, a mask pattern corresponding to the target pattern and including a plurality of rectangular regions. The evaluation unit evaluates the mask pattern using a cost function having, as a parameter, a jog length indicating a length of each of the rectangular regions included in the mask pattern in a first direction. The conversion unit converts mask pattern data indicating the mask pattern with an evaluation that meets a predetermined condition to drawing data corresponding to a variable shaped beam drawing process.

Exemplary embodiments of a data generation apparatus, a data generation method, and a computer-readable storage medium will be explained below in detail with reference to the accompanying drawings. The present invention is not limited to the following embodiments. Also, the components in the following embodiments include ones that can be easily conceived by those skilled in the art or substantially identical ones.

### First Embodiment

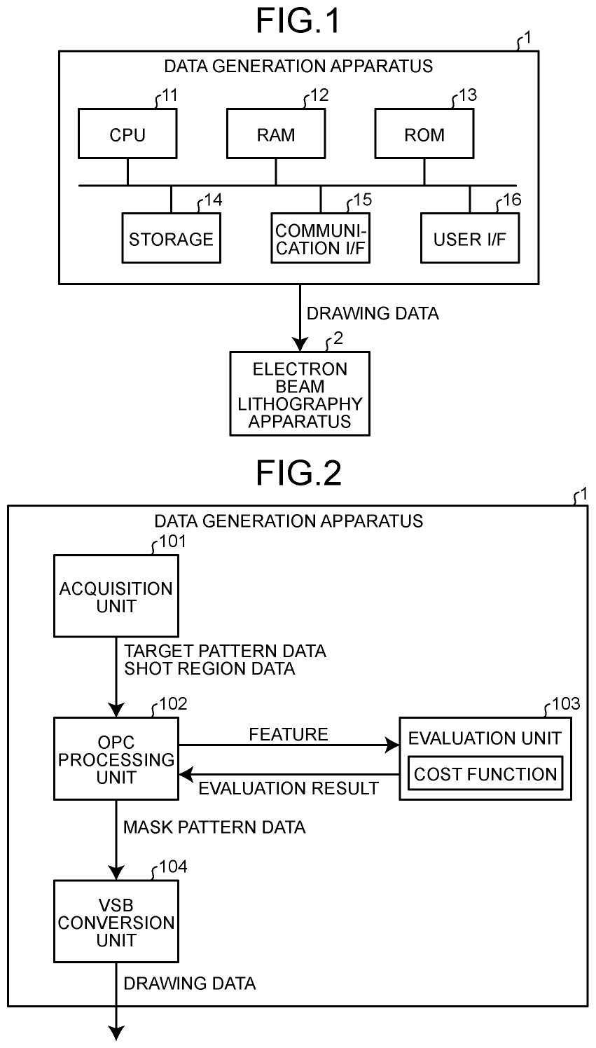

FIG. 1 is a diagram illustrating an example of the hardware configuration of a data generation apparatus 1 of a first embodiment. The data generation apparatus 1 is an information processing apparatus that executes a process for generating drawing data used in an electron beam lithography apparatus 2. The electron beam lithography apparatus 2 is an apparatus that forms a mask pattern on a photomask (reticle) through a variable shaped beam drawing process and forms a predetermined mask pattern on the photomask based on drawing data generated by the data generation apparatus 1.

The data generation apparatus 1 of the present embodiment is configured with a computer including a central processing unit (CPU) 11, a random access memory (RAM) 12, a read only memory (ROM) 13, a storage 14, a communication interface (I/F) 15, a user I/F 16, and the like.

The CPU 11 executes a predetermined arithmetic process using the RAM 12 as a work area in accordance with a program stored in the ROM 13 or the storage 14. The storage 14 is a nonvolatile memory such as a solid state drive (SSD) or a hard disk drive (HDD) and enables writing and reading of a program, data required for processing of the CPU 11, and data generated by processing of the CPU 11. The communication I/F 15 is a device that enables transmission and reception of data to and from an external device (such as the electron beam lithography apparatus 2) connected through a predetermined network such as a local area network (LAN) or a wide area network (WAN). The user I/F 16 is a device that enables reception of input from a user and output of information to a user and can be, for example, a keyboard, a pointing device, a touch panel mechanism, a display, a speaker, or a microphone. The CPU 11, the RAM 12, the ROM 13, the storage 14, the communication I/F 15, and the user I/F 16 are connected through a data bus.

The hardware configuration of the data generation apparatus 1 is not limited to the above-mentioned configuration, and may be a configuration using, for example, a field programmable gate array (FPGA) or an application specific integrated circuit (ASIC) or a configuration in which a plurality of computers operate in conjunction with each other.

FIG. 2 is a diagram illustrating an example of the function configuration of the data generation apparatus 1 of the first embodiment. The data generation apparatus 1 of the present embodiment includes an acquisition unit 101, an OPC processing unit 102, an evaluation unit 103, and a VSB conversion unit 104. These function units 101 to 104 can be implemented, for example, by the cooperation of hardware elements of the data generation apparatus 1 as illustrated in FIG. 1 and software elements (such as a program). Also, some or all of these function units 101 to 104 may be configured with dedicated hardware (such as a circuit).

The acquisition unit 101 acquires various types of data required to generate drawing data. The “acquisition” described herein includes input and generation. The acquisition unit 101 acquires target pattern data and shot region data.

The target pattern data is data indicating a target pattern (e.g., a resist pattern) that is formed on a predetermined substrate through photolithography executed using a photomask with a mask pattern formed thereon. The target pattern data includes information indicating the shape, size, and the like of the target pattern.

The shot region data is data related to a maximum shot region of the electron beam lithography apparatus 2. The maximum shot region is a maximum region that can be drawn with one electron beam irradiation (one shot) when the electron beam lithography apparatus 2 performs a VSB drawing process. The shot region data includes information indicating a maximum shot length, a maximum shot width, and the like. The maximum shot length is the length of the shot region in a predetermined first direction, and the maximum shot width is the length of the shot region in a second direction intersecting the first direction. The first direction, the second direction, the maximum shot length, and the maximum shot width will be explained further below.

The OPC processing unit 102 designs a mask pattern through optical proximity correction (OPC) based on the target pattern indicated by the target pattern data acquired by the acquisition unit 101. The OPC of the present embodiment is a process of designing the mask pattern from the target pattern taking into consideration an optical proximity effect that occurs in forming the target pattern on a substrate through photolithography using the photomask and executed by using a method such as edge based OPC. The edge based OPC is an OPC method characterized by dividing each polygon constituting a mask pattern into one or more edges. This is a technique that evaluates an edge placement error (EPE) between a resist pattern that is estimated from a mask pattern by simulation and formed on a substrate and a desired resist pattern (target pattern) that should be formed on the substrate and corrects the mask pattern by correcting the above-mentioned edge in a direction for reducing the EPE.

The evaluation unit 103 evaluates the mask pattern using a cost function having, as parameters, features related to the shape of the mask pattern designed by the OPC processing unit 102. The cost function is a function that can calculate a cost value indicating an evaluation of the mask pattern by substituting the corresponding feature for each of the parameters. The relationship between the cost value and the evaluation should be appropriately set. For example, the relationship can be set in such a manner that a larger cost value indicates a lower evaluation (a smaller cost value indicates a higher evaluation). The configuration of the cost function will be explained further below.

The evaluation result for each mask pattern obtained by the evaluation unit 103 (the cost value calculated using the cost function) is transferred to the OPC processing unit 102. The OPC processing unit 102 receives the evaluation result and generates, based on the evaluation result, mask pattern data indicating the shape of the mask pattern with an evaluation that meets a predetermined condition. Whether the evaluation meets the predetermined condition can be determined, for example, based on whether the cost value is less than a threshold.

The VSB conversion unit 104 converts the mask pattern data generated by the OPC processing unit 102, that is, the mask pattern data indicating the mask pattern with an evaluation that meets the predetermined condition to drawing data corresponding to the VSB drawing process. A method for converting the mask pattern data to the drawing data is not limited to any particular method, and a known mask data preparation (MDP) technique can be appropriately used. The drawing data generated by the VSB conversion unit 104 is output to the electron beam lithography apparatus 2 and used for the process of drawing the mask pattern on a photoresist.

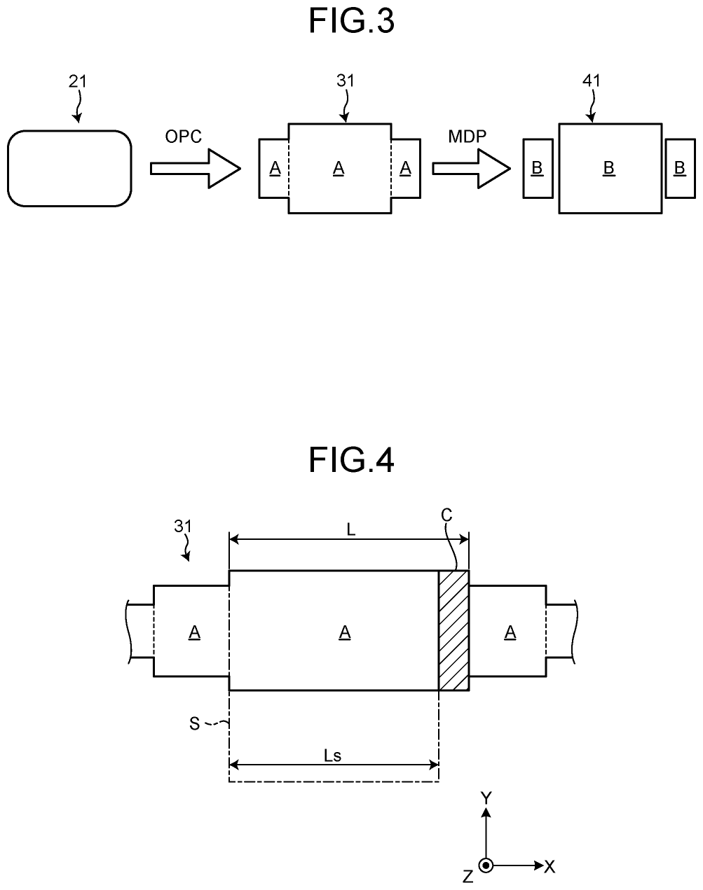

FIG. 3 is a diagram illustrating an example of a target pattern 21, a mask pattern 31, and a VSB drawing pattern 41 of the first embodiment. The target pattern 21 is a desired pattern formed on a surface (a surface to be processed) of a substrate processed through photolithography using a photomask and can be, for example, a resist pattern formed on a resist.

The mask pattern 31 is a pattern that is designed through OPC based on the target pattern 21 and formed on the photomask. The mask pattern 31 of the present embodiment includes a plurality of rectangular regions A. The mask pattern 31 illustrated herein consists of a combination of three rectangular regions A.

The VSB drawing pattern 41 is a pattern that is designed through MDP based on the mask pattern 31 and used when the electron beam lithography apparatus 2 forms the mask pattern 31 on the photomask through the VSB drawing process. The VSB drawing pattern 41 includes a plurality of drawing blocks B. The VSB drawing pattern 41 illustrated herein consists of a combination of three drawing blocks B. The shape of the drawing block B is determined in accordance with the specifications of the electron beam lithography apparatus 2, is not limited to a rectangle, and may include, for example, a triangle.

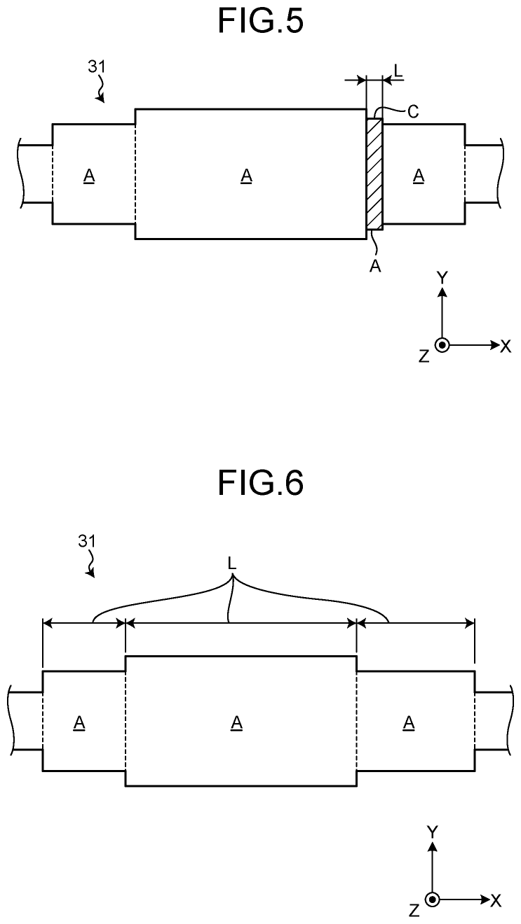

FIG. 4 is a diagram illustrating a first example of the mask pattern 31 of the first embodiment. FIG. 5 is a diagram illustrating a second example of the mask pattern 31 of the first embodiment. In the drawings, an X direction is a direction from left to right of the sheet, a Y direction is a direction from bottom to top of the sheet, and a Z direction is a direction from back to front of the sheet. An XY plane corresponds to the upper face or the lower face of the photomask.

FIG. 4 illustrates a jog length L, a maximum shot region S, and a maximum shot length Ls. The jog length L is the length of the rectangular region A in the X direction (an example of the first direction). Each of the rectangular regions A has a unique jog length L. The maximum shot region S is a maximum region that can be drawn with one electron beam irradiation (one shot) when the electron beam lithography apparatus 2 performs the VSB drawing process. The maximum shot length Ls is the length of the maximum shot region S in the X direction.

The cost function of the present embodiment has the jog length L as a parameter. The following formula (1) shows an example of the cost function of the present embodiment.

$$\\ \begin{matrix}[ Math . 1 ] & \\ Cost = {\sum }_{i} {EPE}_{i}^{2} + {ϵ}_{1} {\sum }_{j} f ( {L}_{j} ) + {ϵ}_{2} {\sum }_{j} g ( {L}_{j} ) & ( 1 )\end{matrix}$$

In formula (1), the first term (ΣEPEᵢ²) on the right side contains a function having, as a parameter, an edge placement error (EPE) value, which is a feature indicating the magnitude of a misalignment between a predetermined part of the target pattern 21 and a predetermined part of the mask pattern 31, a value of the function increasing as the EPE value increases. That is, as the EPE value increases, the cost value (Cost) on the left side increases, and the evaluation of the mask pattern 31 as a subject becomes lower. A method for calculating the EPE value is not limited to any particular method. For example, the EPE value can be calculated based on a result of comparison between an evaluation point set at a predetermined position on the edge of the rectangular region A and a point set at a predetermined position on the target pattern 21. The specific configuration of the function of the first term is not limited to any particular function and can be appropriately configured using a known arithmetic method.

In formula (1), the second term (∈₁Σf(Lⱼ)) on the right side contains a function f (Lⱼ) whose value decreases as the difference between the jog length L and the maximum shot length Ls (a value obtained by subtracting the maximum shot length Ls from the jog length L) decreases when the jog length L is larger than the maximum shot length Ls. ∈₁ is a coefficient, and an optimal numerical value is set for ∈₁ based on a correction result of OPC and the number of steps required for convergence. That is, as illustrated in FIG. 4, when the jog length L is larger than the maximum shot length Ls, the cost value decreases as the difference between the jog length L and the maximum shot length Ls decreases, and convergence of the jog length L to the maximum shot length Ls or less is thus facilitated. This is because, when the jog length L is larger than the maximum shot length Ls, the drawing block B (FIG. 3) needs to be additionally formed on the VSB drawing pattern 41 to draw a narrow region C corresponding to the difference, which increases the number of shots. The specific configuration of the function of the second term should not be limited to any particular configuration. For example, the function can be configured with a sigmoid function or a hyperbolic tangent (tan h) function.

In formula (1), the third term (∈₂Σg(Lⱼ)) on the right side contains a function g (Lⱼ) whose value decreases as the jog length L is closer to zero. ∈₂ is a coefficient, and an optimal numerical value is set for ∈₂ based on a correction result of OPC and the number of steps required for convergence. That is, as illustrated in FIG. 5, when the jog length L is smaller than the maximum shot length Ls (FIG. 4), the cost value decreases as the jog length L decreases, and convergence of the jog length L to zero is facilitated. The drawing block B (FIG. 3) needs to be additionally formed on the VSB drawing pattern 41 to draw a narrow region C corresponding to the jog length L close to zero, which increases the number of shots. Thus, the jog length L is converged to zero. The specific configuration of the function of the third term should not be limited to any particular configuration. For example, the function can be configured with a sigmoid function or a tan h function.

When the mask pattern 31 is evaluated using the cost function as described above and the evaluation does not measure up to a standard (the cost value is equal to or more than the threshold), the mask pattern 31 is redesigned with the jog length L or the like changed. This can converge the shape of the mask pattern 31 to a shape that enables a reduction in the number of shots.

FIG. 6 is a diagram illustrating an example of the shape of the ideal mask pattern 31 of the first embodiment. Designing the mask pattern 31 using the cost function having the jog length L as a parameter as described above facilitates convergence of the jog length L of each of the rectangular regions A within a predetermined range (e.g., a predetermined minimum value or more and the maximum shot length Ls or less). Accordingly, it is possible to prevent the occurrence of the narrow region C as illustrated in FIGS. 4 and 5 and reduce the number of shots in the drawing process performed by the electron beam lithography apparatus 2.

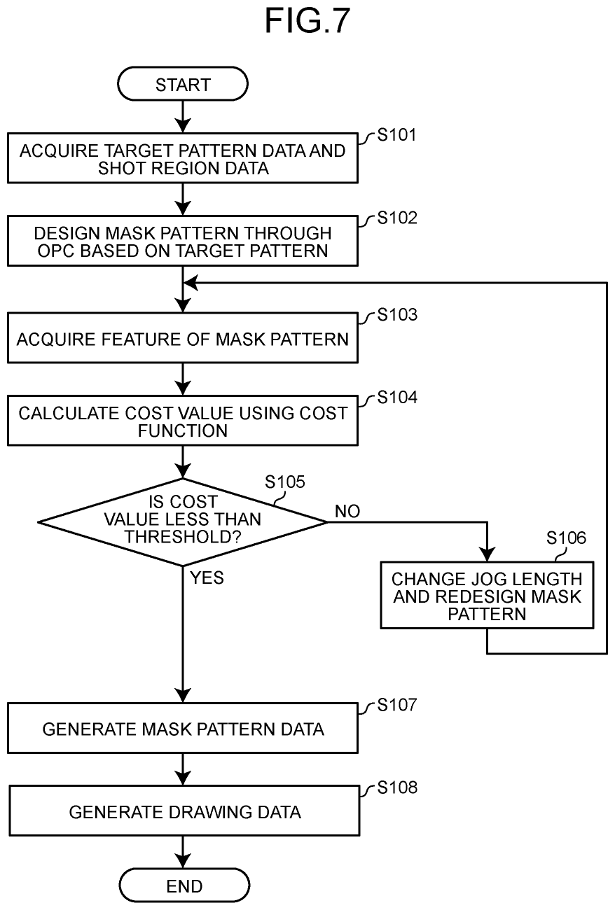

FIG. 7 is a flowchart illustrating an example of the process in the data generation apparatus 1 of the first embodiment. When the acquisition unit 101 acquires target pattern data and shot region data (S101), the OPC processing unit 102 designs the mask pattern 31 through OPC based on the target pattern 21 (S102). The evaluation unit 103 acquires a feature (the jog length L or the like in the present embodiment) of the designed mask pattern 31 (S103) and calculates a cost value using the cost function having the feature as a parameter (S104).

The OPC processing unit 102 acquires the cost value from the evaluation unit 103 and determines whether the cost value of the current mask pattern 31 is less than the threshold (S105). When the cost value is not less than the threshold (S105: No), that is, the evaluation of the current mask pattern 31 does not measure up to the predetermined standard, the OPC processing unit 102 changes the jog length L or the like of the rectangular region A included in the current mask pattern 31 and redesigns the mask pattern 31 (S106). The feature other than the jog length L may be changed.

At this time, although the redesign of the mask pattern 31 changes the EPE value, the position of the evaluation point for calculating the EPE value preferably remains unchanged. That is, the EPE value of the mask pattern 31 after the redesign is preferably calculated based on the same evaluation point as the EPE value of the mask pattern 31 before the redesign. This reduces the computational load in calculating the EPE value and improves the processing speed.

Then, the processes of step S103 and thereafter are executed again. That is, the cost value of the redesigned mask pattern 31 is calculated based on the feature of the redesigned mask pattern 31, and it is determined whether the calculated cost value is less than the threshold.

When the cost value is less than the threshold (S105: Yes), that is, the evaluation of the current mask pattern 31 measures up to the predetermined standard, the OPC processing unit 102 generates mask pattern data indicating the shape or the like of the current mask pattern 31 (S107). Then, the VSB conversion unit 104 designs the VSB drawing pattern 41 based on the mask pattern 31 indicated by the generated mask pattern data and generates drawing data indicating the designed VSB drawing pattern 41 (S108). The drawing data is output to the electron beam lithography apparatus 2, and the mask pattern 31 is formed on a photomask through the VSB drawing process.

As described above, according to the present embodiment, the mask pattern 31 is designed using the cost function having the jog length L as a parameter. Accordingly, it is possible to optimize the jog length L of each of the rectangular regions A based on the relationship between the jog length L and the maximum shot length Ls, a value of the jog length L itself, and the like with high accuracy. As a result, it is possible to reduce the number of shots in the VSB drawing process and improve the productivity of photomasks.

Other embodiments will be explained below with reference to the drawings. Parts that are the same as or similar to those in the first embodiment may be designated by the same reference signs as in the first embodiment to omit description thereof.

### Second Embodiment

A data generation apparatus 1 of a second embodiment differs from the first embodiment in that the cost function has an end misalignment amount, which will be explained further below, as a parameter in addition to the above-mentioned jog length L.

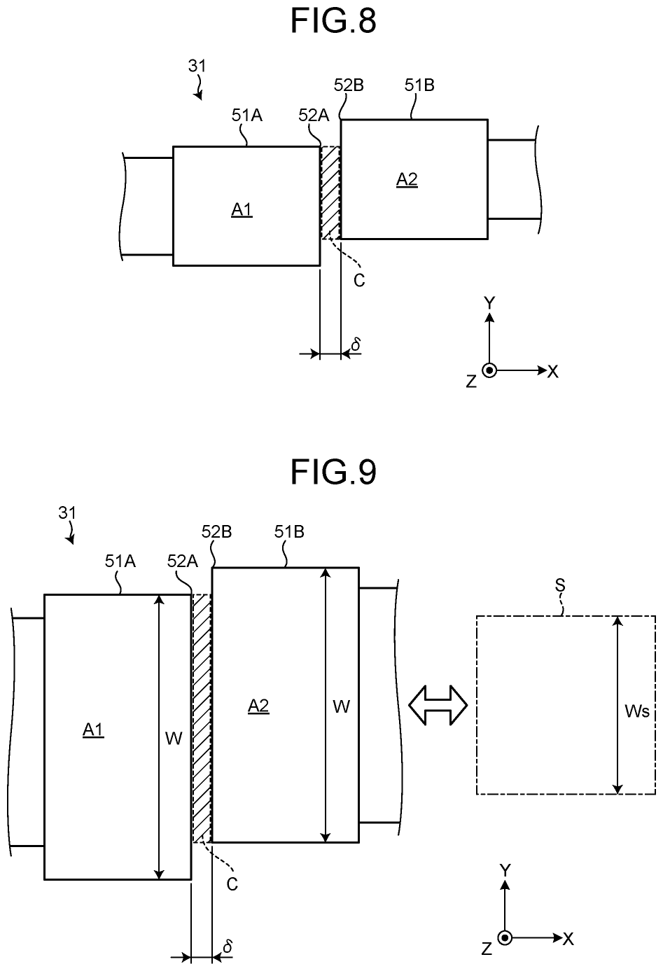

FIG. 8 is a diagram illustrating an example of an end misalignment amount δ in a mask pattern 31 of the second embodiment. FIG. 8 illustrates a first rectangular region A1 and a second rectangular region A2 that are adjacent to each other in the X direction. The end misalignment amount δ is a feature indicating a misalignment in the X direction between an end 52A of an edge 51A of the first rectangular region A1, the edge 51A extending in the X direction, and an end 52B of an edge 51B of the second rectangular region A2, the edge 51B extending in the X direction and the end 52B facing the first rectangular region A1.

The following formula (2) shows an example of the cost function of the present embodiment.

$$\\ \begin{matrix}[ Math . 2 ] & \\ Cost = {\sum }_{i} {EPE}_{i}^{2} + {ϵ}_{1} {\sum }_{j} f ( {L}_{j} ) + {ϵ}_{2} {\sum }_{j} g ( {L}_{j} ) + {ϵ}_{3} {\sum }_{k} h ( {δ}_{k} ) & ( 2 )\end{matrix}$$

The cost function of the present embodiment has the fourth term (∈₃Σh(δₖ)) in addition to the first term (ΣEPEᵢ²), the second term (∈₁Σf(Lⱼ)), and the third term (∈₂Σg(Lⱼ)) described above. The fourth term contains a function h (δₖ) whose value decreases as the end misalignment amount δ is closer to zero. ∈₃ is a coefficient, and an optimal numerical value is set for ∈₃ based on a correction result of OPC and the number of steps required for convergence. That is, as illustrated in FIG. 8, the cost value decreases (the evaluation of the mask pattern 31 becomes higher) as the end misalignment amount δ present between the first rectangular region A1 and the second rectangular region A2 decreases, and convergence of the end misalignment amount δ to zero can thus be facilitated. The presence of a narrow region C corresponding to the slight end misalignment amount δ inside the mask pattern 31 may increase the number of shots. Thus, the number of shots can be reduced by converging the end misalignment amount δ to zero.

As described above, according to the present embodiment, the mask pattern 31 is designed using the cost function having the end misalignment amount δ as a parameter in addition to the jog length L. Accordingly, it is possible to optimize the shape of each of the rectangular regions A so that the slight end misalignment amount δ does not occur. As a result, it is possible to reduce the number of shots in the VSB drawing process and improve the productivity of photomasks.

### Third Embodiment

A data generation apparatus 1 of a third embodiment differs from the second embodiment in that the cost function further has a pattern width, which will be explained further below, as a parameter.

FIG. 9 is a diagram illustrating an example of a pattern width W in a mask pattern 31 and a maximum shot width Ws in a maximum shot region S of the third embodiment. As illustrated in FIG. 9, the pattern width W is a feature indicating the length of each of the rectangular regions A (A1, A2) in the Y direction (an example of the second direction). The maximum shot width Ws is a feature indicating the length of the maximum shot region S in the Y direction.

FIG. 9 illustrates a case in which the pattern width W of each of the first rectangular region A1 and the second rectangular region A2 that are arranged side by side in the X direction is larger than the maximum shot width Ws. The cost function of the present embodiment is configured so that the cost value is not affected by the end misalignment amount δ, that is, the cost value does not decrease even if the end misalignment amount δ decreases when the pattern width W is larger than the maximum shot width Ws as illustrated.

The following formula (3) shows an example of the cost function of the present embodiment.

$$\\ \begin{matrix}[ Math . 3 ] & \\ Cost = {\sum }_{i} {EPE}_{i}^{2} + {ϵ}_{1} {\sum }_{j} f ( {L}_{j} ) + {ϵ}_{2} {\sum }_{j} g ( {L}_{j} ) + {ϵ}_{3} {\sum }_{k} h ( {δ}_{k} , {W}_{k} ) & ( 3 )\end{matrix}$$

The cost function of the present embodiment has the fourth term (∈₃Σh(δₖ, Wₖ)) in addition to the first term (ΣEPEᵢ²), the second term (∈₁Σf(Lⱼ)), and the third term (∈₂Σg(Lⱼ)) described above. ∈₃ is a coefficient, and an optimal numerical value is set for ∈₃ based on a correction result of OPC and the number of steps required for convergence. The fourth term of the present embodiment contains a function h (δₖ, Wₖ) whose value decreases as the end misalignment amount δ is closer to zero only when the pattern width W is equal to or smaller than the maximum shot width Ws. That is, as illustrated in FIG. 9, when the pattern width W of each of the first rectangular region A1 and the second rectangular region A2 is larger than the maximum shot width Ws, the end misalignment amount δ between the first rectangular region A1 and the second rectangular region A2 does not affect the cost value. This is because, in such a case, the first rectangular region A1 and the second rectangular region A2 are divided in the Y direction in designing the VSB drawing pattern 41, and the narrow region C corresponding to the end misalignment amount δ thus does not cause an increase in the number of shots.

As described above, according to the present embodiment, the mask pattern 31 is designed using the cost function that has the pattern width W as a parameter and changes the influence of the end misalignment amount δ on the cost value in accordance with the relationship between the pattern width W and the maximum shot width Ws. This prevents an increase in the cost value caused by taking the end misalignment amount δ into consideration when the end misalignment amount δ does not need to be taken into consideration. Accordingly, it is possible to avoid unnecessary redesign of the mask pattern 31 and reduce the computational load and the processing time for the design of the mask pattern 31.

### Fourth Embodiment

While the configurations that use the cost functions having the jog length L as a parameter have been described in the first to third embodiments, for example, a cost function that does not have the jog length L and has the end misalignment amount δ as a parameter as with the following formula (4) may be used. Note that E is a coefficient, and an optimal numerical value is set for E based on a correction result of OPC and the number of steps required for convergence.

$$\\ \begin{matrix}[ Math . 4 ] & \\ Cost = {\sum }_{i} {EPE}_{i}^{2} + ϵ {\sum }_{k} h ( {δ}_{k} ) & ( 4 )\end{matrix}$$

Even when such a cost function is used, it is possible to optimize the mask pattern 31 based on the end misalignment amount δ and reduce the number of shots.

(Modification)

In the above embodiments, the case in which the mask pattern 31 is designed through the OPC based on the target pattern 21, and the VSB drawing pattern 41 is designed through the MDP based on the mask pattern 31 has been described (refer to FIG. 3). However, the data generation apparatus 1 of the present embodiment can also be used in a case in which an ILT pattern is designed through an inverse lithography technology (ILT) based on the target pattern 21, and the above-mentioned mask pattern is designed through a Manhattanize process based on the ILT pattern. Here, the Manhattanize process is a process of converting the mask pattern into a Manhattan shape (such as a linear polygon) that does not violate manufacturing rules.

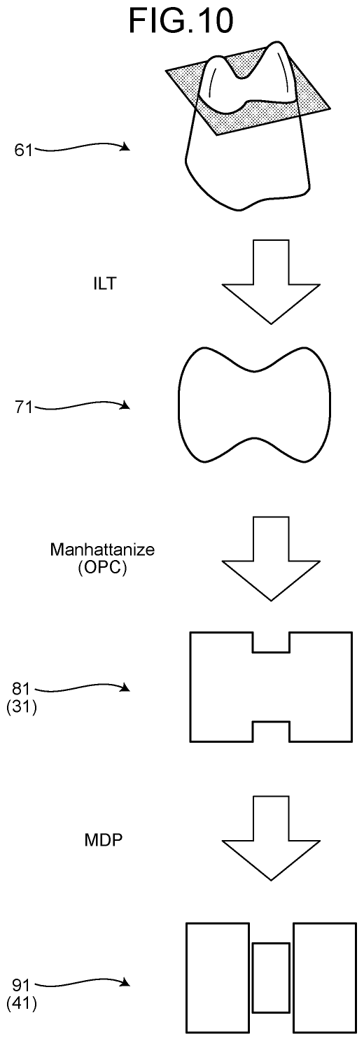

FIG. 10 is a diagram illustrating an example of the process in designing a VSB drawing pattern 91 from a target pattern 61 using the ILT in a modification. As illustrated in FIG. 10, an ILT pattern 71 representing the shape of the target pattern 61 on one plane is designed by performing the ILT process using a level set function based on the target pattern 61 representing a 3D shape. Then, a mask pattern 81 having a configuration similar to that of the mask pattern 31 described above is designed by performing the Manhattanize process based on the ILT pattern 71. Then, the VSB drawing pattern 91 having a configuration similar to that of the VSB drawing pattern 41 described above is designed through MDP based on the mask pattern 81.

Using the cost function as described above in the Manhattanize process makes it possible to optimize the mask pattern 81 as with the above embodiments and generate drawing data that enables a reduction in the number of shots.

The program that causes the computer (information processing apparatus) constituting the data generation apparatus 1 to execute a predetermined process to implement the functions of the data generation apparatus 1 as described above may be recorded on a computer-readable recording medium such as a CD-ROM, a flexible disk (FD), a CD-R, or a digital versatile disk (DVD) as a file in the computer-installable or executable format to be provided. The program may be stored in a computer connected to a network such as the Internet and downloaded via the network to be provided. The program may be provided or distributed via a network such as the Internet.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

(Supplement)

In the following, the contents of the above-mentioned embodiments are appended.

(Supplement 1)

A data generation apparatus that executes a process for generating drawing data for forming a mask pattern on a photomask, in which
the data generation apparatus
designs, through optical proximity correction based on a target pattern formed on a substrate using the photomask, the mask pattern corresponding to the target pattern and including a plurality of rectangular regions,
evaluates the mask pattern using a cost function having, as a parameter, an end misalignment amount indicating a misalignment in a first direction between an end of an edge of a first rectangular region, the edge extending in the first direction, and an end of an edge of a second rectangular region adjacent to the first rectangular region in the first direction, the edge extending in the first direction and the end facing the first rectangular region, and
converts mask pattern data indicating the mask pattern with an evaluation that meets a predetermined condition to drawing data corresponding to a variable shaped beam drawing process.

What is claimed is:

1. A data generation apparatus comprising a computer that executes a process for generating drawing data for forming a mask pattern on a photomask, wherein
the computer
designs, through optical proximity correction based on a target pattern formed on a substrate using the photomask, the mask pattern corresponding to the target pattern and including a plurality of rectangular regions,
evaluates the mask pattern using a cost function having, as a parameter, a jog length indicating a length of each of the rectangular regions included in the mask pattern in a first direction, and
converts mask pattern data indicating the mask pattern with an evaluation that meets a predetermined condition to drawing data corresponding to a variable shaped beam drawing process.

2. The data generation apparatus according to claim 1, wherein,
when the jog length is larger than a maximum shot length indicating a length of a maximum shot region in the first direction in the drawing process, the computer makes the evaluation higher as a difference between the jog length and the maximum shot length decreases.

3. The data generation apparatus according to claim 2, wherein
the computer makes the evaluation higher as the jog length is closer to zero.

4. The data generation apparatus according to claim 1, wherein
the cost function has, as a parameter, an end misalignment amount indicating a misalignment in the first direction between an end of an edge of a first rectangular region, the edge extending in the first direction, and an end of an edge of a second rectangular region adjacent to the first rectangular region in the first direction, the edge extending in the first direction and the end facing the first rectangular region.

5. The data generation apparatus according to claim 4, wherein
the computer makes the evaluation higher as the end misalignment amount is closer to zero.

6. The data generation apparatus according to claim 5, wherein,
when a pattern width indicating a length of the rectangular region in a second direction intersecting the first direction is larger than a maximum shot width indicating a length of a maximum shot region in the second direction in the drawing process, the end misalignment amount does not affect the evaluation.

7. The data generation apparatus according to claim 1, wherein
the cost function has, as a parameter, an EPE value indicating a misalignment between a predetermined part of the target pattern and a predetermined part of the mask pattern, the EPE value being calculated based on an evaluation point set on an edge of each of the rectangular region, and
the EPE value is calculated with a position of the evaluation point unchanged in designing a plurality of the mask patterns with the jog length changed in the optical proximity correction.

8. The data generation apparatus according to claim 1, wherein
the computer performs an inverse lithography technology (ILT) process based on the target pattern in the optical proximity correction.

9. A data generation method for generating drawing data for forming a mask pattern on a photomask using a computer, the method comprising:
by the computer
designing, through optical proximity correction based on a target pattern formed on a substrate using the photomask, the mask pattern corresponding to the target pattern and including a plurality of rectangular regions;
evaluating the mask pattern using a cost function having, as a parameter, a jog length indicating a length of each of the rectangular regions included in the mask pattern in a first direction; and
converting mask pattern data indicating the mask pattern with an evaluation that meets a predetermined condition to drawing data corresponding to a variable shaped beam drawing process.

10. A computer-readable storage medium on which a program that causes a computer to execute a process for generating drawing data for forming a mask pattern on a photomask through a variable shaped beam method is stored, wherein
the program causes the computer to execute
a process of designing, through optical proximity correction based on a target pattern formed on a substrate using the photomask, the mask pattern corresponding to the target pattern and including a plurality of rectangular regions,
a process of evaluating the mask pattern using a cost function having, as a parameter, a jog length indicating a length of each of the rectangular regions included in the mask pattern in a first direction, and
a process of converting mask pattern data indicating the mask pattern with an evaluation that meets a predetermined condition to drawing data corresponding to a variable shaped beam drawing process.
